(19) United States
(12) Patent Application Publication
(10) Pub. No.: US 2008/0169021 A1
(43) Pub. Date: Jul. 17, 2008

(54) Method of making TCO front electrode for use in photovoltaic device or the like

(75) Inventor: Alexey Krasnov, Canton, MI (US)

Correspondence Address: NIXON & VANDERHYE, PC, 901 NORTH GLEBE ROAD, 11TH FLOOR, ARLINGTON, VA, 22203, US

(73) Assignee: Guardian Industries Corp., Auburn Hills, MI (US)

(21) Appl. No.: 11/653,431

(22) Filed: Jan. 16, 2007

(51) Int. Cl. H01L 31/18; C23C 14/06

(52) U.S. Cl. 136/256; 204/192.1

(57) ABSTRACT

Certain example embodiments of this invention relate to an electrode (e.g., front electrode) for use in a photovoltaic device or the like. In certain example embodiments, a transparent conductive oxide (TCO) based front electrode for use in a photovoltaic device may be made by sputtering a ceramic target in a gaseous atmosphere tailored to optimize the electro-optical properties of the resulting TCO coating. For example, using a particular type of atmosphere in the sputtering process can permit the resulting TCO coating (e.g., of or including zinc oxide, zinc aluminum oxide, and/or ITO) to more readily withstand subsequent high temperature processing which may be used during manufacture of the photovoltaic device. Moreover, processing energy resulting from the high temperature(s) may also optionally be used to improve crystallinity characteristics of the TCO.

Certain example embodiments of this invention relate to a method of making an electrode (e.g., front electrode) for use in a photovoltaic device or the like. In certain example embodiments, a transparent conductive oxide (TCO) based front electrode for use in a photovoltaic device is of or includes zinc oxide, zinc aluminum oxide, indium-tin-oxide (ITO), or any other suitable material. In certain example embodiments of this invention, a deposition technique is used to form the TCO which causes improved electrical conductivity of the resulting TCO for use in the electrode, before and/or after subsequent optional heat processing.

### BACKGROUND AND SUMMARY OF EXAMPLE EMBODIMENTS OF INVENTION

Photovoltaic devices are known in the art (e.g., see U.S. Pat. Nos. 6,784,361, 6,288,325, 6,613,603 and 6,123,824, the disclosures of which are hereby incorporated herein by reference). Amorphous silicon (a-Si) and CdTe type photovoltaic devices, for example, each include a front contact or electrode.

Pyrolitic SnO₂:F transparent conductive oxide (TCO) is often used as a front transparent electrode in photovoltaic devices. One advantage of pyrolitic SnO₂:F for use as a TCO front electrode in photovoltaic devices is that it is able to withstand high processing temperatures used in making the devices. However, from the viewpoint of uniformity, potential cost savings, and film smoothness, pyrolytically deposited TCOs are not desirable. Thus, it will be appreciated that a sputter-deposited TCO for use as an electrode in a photovoltaic device would be more desirable with respect to one or more of uniformity, cost savings and/or film smoothness.

In certain example instances, it is possible for the front electrode of a photovoltaic device to be made of a transparent conductive oxide (TCO) such as tin oxide, zinc oxide (possibly doped with Al, i.e., ZnAlOₓ), or indium-tin-oxide (ITO) formed via sputtering on a substrate such as a glass substrate. However, in certain applications, such as CdTe photovoltaic devices as an example, high processing temperatures (e.g., 550-600 degrees C.) are used during manufacturing. High processing temperatures (e.g., 220-300 degrees C. or higher, with an example being about 250 degrees C.) may also be used in making a-Si and/or micromorph solar cells.

Unfortunately, conductive sputter-deposited TCOs such as ZnAlOₓ and ITO formed in a conventional sputtering process tends to lose significant amounts of electrical conductivity when heated to high temperatures (high temperatures may be needed in photovoltaic device manufacturing in certain instances). This loss of conductivity may be caused by fast oxygen migration from grain boundaries into the bulk of the crystallites. Moreover, at extremely high temperatures (e.g., 625-650 degrees C), structural transformation of zinc oxide starts to occur.

It is apparent from the above that there exists a need in the art for an improved TCO material for use in photovoltaic devices or the like. In certain example embodiments of this invention, there exists a need in the art for a technique for making or forming a TCO electrode using sputtering in a manner which improves the TCO's electrical conductivity as deposited and/or after high temperature processing. In certain example embodiments of this invention, sputtering is used in a manner so that the resulting TCO electrode still has acceptable conductivity even after exposure to high temperatures.

It has been found that by sputtering a ceramic target(s) in a particular type of atmosphere to form a TCO coating/electrode, the electro-optical properties of the resulting TCO coating/electrode can be optimized. For example, using a particular type of atmosphere in the sputtering process can permit the resulting TCO coating to more readily withstand subsequent high temperature processing which may be used during manufacture of the photovoltaic device. Moreover, processing energy resulting from the high temperature(s) may also optionally be used to improve crystallinity characteristics of the TCO coating.

In certain example embodiments of this invention, a TCO coating/electrode (e.g., of or including zinc oxide and/or indium-tin-oxide) may be sputter-deposited using a ceramic sputtering target(s) in an atmosphere including both argon (Ar) and oxygen (O₂) gases. In certain example embodiments, the oxygen content of the atmosphere used in sputtering is adjusted so as to optimize the electro-optical properties of the resulting TCO coating/electrode. In certain example embodiments, the atmosphere used in sputter-depositing a zinc oxide based or inclusive TCO coating (which may optionally be doped with Al or the like) has an oxygen gas to total gas ratio (e.g., O₂/(Ar+O₂) ratio) of from 0 to 0.0025, more preferably from about 0.00001 to 0.0025, still more preferably from about 0.0001 to 0.002, even more preferably from about 0.0001 to 0.0015, and most preferably from about 0.0001 to 0.0010, with an example ratio being about 0.0005. In other example embodiments, the atmosphere used in sputter-depositing an ITO based or inclusive TCO coating has an oxygen gas to total gas ratio (e.g., O₂/(Ar+O₂)) of from 0.003 to 0.017, more preferably from about 0.004 to 0.016, still more preferably from about 0.005 to 0.015, even more preferably from about 0.008 to 0.014, with an example ratio being about 0.011. Surprisingly, it has been found that these gas ratios cause the electrical conductivity of the sputter-deposited TCO coating to be improved before and/or after subsequent high temperature processing (e.g., high temperature processing used in photovoltaic device manufacturing). Moreover, it has also unexpectedly been found that these gas ratios are advantageous in that they allow the optional subsequent high temperature processing to be used to improve the crystallinity of the TCO coating thereby resulting in a highly conductive and satisfactory TCO coating which may be used in applications such as electrodes in photovoltaic devices and the like. The sputtering may be performed at approximately room temperature in certain example embodiments, although other temperatures may be used in certain instances.

In certain example embodiments, the TCO electrode may be used as any suitable electrode in any suitable electronic device, such as a photovoltaic device, a flat-panel display device, and/or an electro-optical device. TCO coatings according to different example embodiments of this invention may be used in either monolithic or multistack configurations in different instances. In certain example embodiments of this invention, the TCO electrode or film may have a sheet resistance (Rₛ) of from about 7-50 ohms/square, more preferably from about 10-25 ohms/square, and most preferably from about 10-15 ohms/square using a reference example non-limiting thickness of from about 1,000 to 2,000 angstroms.

In certain example embodiments of this invention, there is provided a method of making a photovoltaic device, the method comprising: providing a glass substrate; sputtering at least one ceramic target in an atmosphere in order to deposit a substantially transparent conductive electrode comprising zinc oxide on the glass substrate; wherein the ceramic target comprises zinc oxide; wherein the atmosphere in which the target is sputtered includes both argon and oxygen gas and has an oxygen gas to total gas ratio of from 0.00001 to 0.0025; and using the glass substrate with at least the electrode thereon in making a photovoltaic device which includes at least one semiconductor film.

In certain example embodiments of this invention, there is provided a method of making an electrode for use in an electronic device (e.g., photovoltaic device, display device, circuit board, electro-optical device, etc.), the method comprising: providing a glass substrate; sputtering at least one ceramic target in an atmosphere in order to deposit a substantially transparent conductive electrode comprising zinc oxide on the glass substrate; wherein the ceramic target comprises zinc oxide; and wherein the atmosphere in which the target is sputtered includes both argon and oxygen gas and has an oxygen gas to total gas ratio of from 0.00001 to 0.0025.

In still further example embodiments of this invention, there is provided a method of making a photovoltaic device, the method comprising: providing a glass substrate; sputtering at least one ceramic target in an atmosphere in order to deposit a substantially transparent conductive electrode comprising indium tin oxide on the glass substrate; wherein the ceramic target comprises indium tin oxide; wherein the atmosphere in which the target is sputtered includes both argon and oxygen gas and has an oxygen gas to total gas ratio of from 0.003 to 0.017; and using the glass substrate with at least the electrode thereon in making a photovoltaic device which includes at least one semiconductor film.

In other example embodiments of this invention, there is provided a method of making an electrode for use in an electronic device, the method comprising: providing a glass substrate; sputtering at least one ceramic target in an atmosphere in order to deposit a substantially transparent conductive electrode comprising indium tin oxide on the glass substrate; wherein the ceramic target comprises indium tin oxide; and wherein the atmosphere in which the target is sputtered includes both argon and oxygen gas and has an oxygen gas to total gas ratio of from 0.003 to 0.017.

### BRIEF DESCRIPTION OF THE DRAWINGS

FIG. 1 is a cross sectional view of an example photovoltaic device according to an example embodiment of this invention.

FIG. 2 is a cross sectional view of an example photovoltaic device according to another example embodiment of this invention.

FIG. 3 is a cross sectional view of an example photovoltaic device according to yet another example embodiment of this invention.

FIG. 4 is a conductivity versus gas ratio graph illustrating advantages of certain gas ratios used in sputtering according to certain example embodiments of this invention.

### DETAILED DESCRIPTION OF EXAMPLE EMBODIMENTS OF THE INVENTION

Referring now more particularly to the drawings in which like reference numerals indicate like parts throughout the several views.

Photovoltaic devices such as solar cells convert solar radiation and other light into usable electrical energy. The energy conversion occurs typically as the result of the photovoltaic effect. Solar radiation (e.g., sunlight) impinging on a photovoltaic device and absorbed by an active region of semiconductor material (e.g., a semiconductor film including one or more semiconductor layers such as a-Si layers, or any other suitable semiconductor material) generates electron-hole pairs in the active region. The electrons and holes may be separated by an electric field of a junction in the photovoltaic device. The separation of the electrons and holes by the junction results in the generation of an electric current and voltage. In certain example embodiments, the electrons flow toward the region of the semiconductor material having n-type conductivity, and holes flow toward the region of the semiconductor having p-type conductivity. Current can flow through an external circuit connecting the n-type region to the p-type region as light continues to generate electron-hole pairs in the photovoltaic device.

In certain example embodiments, single junction amorphous silicon (a-Si) photovoltaic devices include three semiconductor layers which make up a semiconductor film. In particular, a p-layer, an n-layer and an i-layer which is intrinsic. The amorphous silicon film (which may include one or more layers such as p, n and i type layers) may be of hydrogenated amorphous silicon in certain instances, but may also be of or include hydrogenated amorphous silicon carbon or hydrogenated amorphous silicon germanium, or the like, in certain example embodiments of this invention. For example and without limitation, when a photon of light is absorbed in the i-layer it gives rise to a unit of electrical current (an electron-hole pair). The p and n-layers, which contain charged dopant ions, set up an electric field across the i-layer which draws the electric charge out of the i-layer and sends it to an optional external circuit where it can provide power for electrical components. It is noted that while certain example embodiments of this invention are directed toward amorphous-silicon based photovoltaic devices, this invention is not so limited and may be used in conjunction with other types of photovoltaic devices in certain instances including but not limited to devices including other types of semiconductor material, tandem thin-film solar cells, and the like.

Certain example embodiments of this invention may also be applicable to CdS/CdTe type photovoltaic devices, especially given the high processing temperatures often utilized in making CdTe type photovoltaic devices. Moreover, TCO electrodes according to different embodiments of this invention may also be used in connection with CIS/CIGS and/or tandem a-Si type photovoltaic devices.

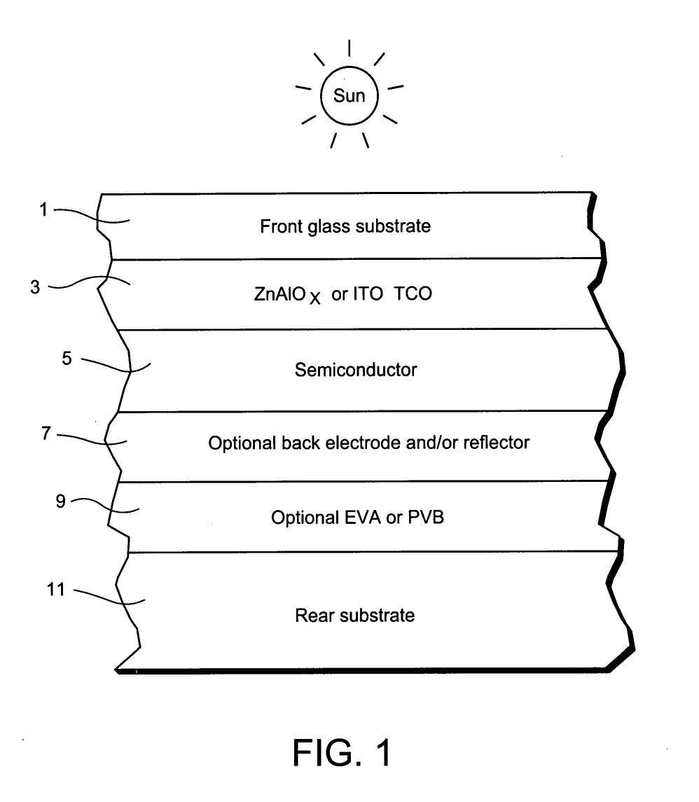

FIG. 1 is a cross sectional view of a photovoltaic device according to an example embodiment of this invention. The photovoltaic device includes transparent front substrate 1 of glass or the like, front electrode or contact 3 which is of or includes a TCO such as ZnOₓ, ZnAlOₓ, and/or indium tin oxide (ITO), active semiconductor film 5 of one or more semiconductor layers, optional back electrode or contact 7 which may be of a TCO or a metal, an optional encapsulant 9 or adhesive of a material such as ethyl vinyl acetate (EVA), polyvinyl butyral (PVB), or the like, and an optional rear substrate II of a material such as glass or the like. The semiconductor layer(s) of film 5 may be of or include one or more of a-Si, CdTe, CdS, or another other suitable material, in different example embodiments of this invention. Of course, other layer(s) which are not shown may be provided in the device, such as between the front glass substrate 1 and the front electrode 3, or between other layers of the device.

It has been found that by sputtering a ceramic target(s) in a particular type of atmosphere to form TCO coating 3, the electro-optical properties of the resulting TCO coating/electrode 3 can be optimized. For example, using a particular type of atmosphere in the sputtering process can permit the resulting TCO coating/electrode 3 to more readily withstand subsequent high temperature processing which may be used during manufacture of the photovoltaic device. Moreover, processing energy resulting from the high temperature(s) may also optionally be used to improve crystallinity characteristics of the TCO coating/electrode 3.

In certain example embodiments of this invention, the TCO coating/electrode 3 (e.g., of or including zinc oxide, zinc aluminum oxide, and/or indium-tin-oxide) may be sputter-deposited using a ceramic sputtering target(s) in an atmosphere including both argon (Ar) and oxygen (O₂) gases. For example, when sputtering depositing a layer of zinc oxide for TCO electrode 3, the ceramic target(s) used in such sputtering can be of zinc oxide; when sputter depositing a layer of zinc aluminum oxide for TCO electrode 3, the ceramic target(s) used in such sputtering can be of zinc aluminum oxide; and/or when sputter depositing a layer of indium-tin-oxide (ITO) for TCO electrode 3, the ceramic target(s) used in such sputtering can be of ITO.

In certain example embodiments, the oxygen content of the gaseous atmosphere used in sputtering to form coating/electrode 3 is adjusted so as to optimize the electro-optical properties of the resulting TCO coating/electrode 3. In certain example embodiments, the atmosphere used in sputter-depositing a zinc oxide based or inclusive TCO coating/electrode 3 (which may optionally be doped with Al or the like) has an oxygen gas to total gas ratio (e.g., O₂/(Ar+O₂) ratio) of from 0 to 0.0025, more preferably from about 0.00001 to 0.0025, still more preferably from about 0.0001 to 0.002, even more preferably from about 0.0001 to 0.0015, and most preferably from about 0.0001 to 0.0010, with an example ratio being about 0.0005. In such example embodiments, the TCO electrode 3 may consist or consist essentially of zinc oxide, or alternatively may be doped with a metal such as Al or the like. For example, in certain example instances, such a TCO electrode 3 may include from about 0-10% Al, more preferably from about 0.5-10% Al, even more preferably from about 1-5% Al, still more preferably from about 1-3% Al, with an example amount of Al dopant in electrode/coating 3 being about 2.0% (wt. %).

In other example embodiments, the atmosphere used in sputter-depositing an ITO based or inclusive TCO coating/electrode 3 has an oxygen gas to total gas ratio (e.g., O₂/(Ar+O₂) ratio) of from 0.003 to 0.017, more preferably from about 0.004 to 0.016, still more preferably from about 0.005 to 0.015, even more preferably from about 0.008 to 0.014, with an example ratio being about 0.011. In certain example instances, an ITO coating/electrode 3 may include in the metal portion thereof (made up of for example the total In and Sn content, not including oxygen content): from about 50-99% indium (In), more preferably from about 60-98% In, still more preferably from about 70-95% In, most preferably from about 80-95% In, with an example amount of In in the coating/electrode 3 being about 90% (wt. %); and from about 1-50% Sn, more preferably from about 2-40% Sn, even more preferably from about 5-30% Sn, still more preferably from about 5-20% Sn, with an example Sn amount being about 10% Sn (wt. %). Thus, in certain example embodiments, the coating/electrode 3 includes more In than Sn, more preferably at least twice at much In as Sn, even more preferably at least about five times as much In as Sn, and possibly about nine times as much In as Sn. For example, in an example ITO coating electrode, the In/Sn ratio may be about 90/10 wt % in certain example instances. The above percentages of In and Sn, and the above ratios, may also apply to the overall ITO based coating/electrode 3 in certain example embodiments.

Surprisingly, it has been found that the above gas ratios cause the electrical conductivity of the sputter-deposited TCO electrode/coating 3 to be improved before and/or after subsequent high temperature processing (e.g., high temperature processing used in photovoltaic device manufacturing). Example temperatures for the optional subsequent processing may include temperatures of at least about 220 degrees C. (e.g., for a-Si and/or micromorph photovoltaic devices), possibly of at least about 240 degrees C., possibly of at least about 500 degrees C., possibly of at least about 550 degrees C. (e.g., for CdTe devices), and possibly of at least about 600 or 625 degrees C. Additionally, the resulting electrode 3 can realize reduced or no structural transformation at optional subsequent high temperatures. Moreover, it has also unexpectedly been found that these gas ratios are advantageous in that they allow the optional subsequent high temperature processing to be used to improve the crystallinity of the TCO coating/electrode 3 thereby resulting in a highly conductive and satisfactory TCO coating/electrode 3 which may be used in applications such as electrodes 3 (and possibly 7) in photovoltaic devices and the like. The sputtering may be performed at approximately room temperature in certain example embodiments, although other temperatures may be used in certain instances.

The ceramic target(s) used in sputter-depositing electrode/coating 3 may be of any suitable type in certain example embodiments of this invention. For example, rotating magnetron type targets or stationary planar targets may be used in certain example instances.

In certain example embodiments, the TCO electrode 3 of one or more layers may have a sheet resistance (Rₛ) of from about 7-50 ohms/square, more preferably from about 10-25 ohms/square, and most preferably from about 10-15 ohms/square using a reference example non-limiting thickness of from about 1,000 to 2,000 angstroms. These sheet resistance values apply before and/or after any optional heat treatment or high temperature processing.

Sputter deposition of TCO coating/electrode 3 at approximately room temperature on (directly or indirectly) substrate 1 would be desirable in certain example embodiments, given that most float glass manufacturing platforms are not equipped with in-situ heating systems. Moreover, an additional potential advantage of sputter-deposited TCO films is that they may include the integration of anti-reflection coatings (not shown), resistivity reduction, and so forth. For example, a single or multi-layer anti-reflection coating (not shown) may be provided between the glass substrate 1 and the TCO front electrode 3 in photovoltaic applications in certain example instances.

In certain example embodiments, the substantially transparent electrode 3 has a visible transmission of at least about 50%, more preferably of at least about 60%, even more preferably of at least about 70% or 80%. In certain example embodiments of this invention, the TCO front electrode or contact 3 is substantially free, or entirely free, of fluorine. This may be advantageous in certain example instances for pollutant issues.

An additional potential advantage of sputter-deposited TCO films for font electrodes/contacts 3 is that they may permit the integration of an anti-reflection and/or colour-compression coating (not shown) between the front electrode 3 and the glass substrate 1. The anti-reflection coating (not shown) may include one or multiple layers in different embodiments of this invention. For example, the anti-reflection coating (not shown) may include a high refractive index dielectric layer immediately adjacent the glass substrate 1 and another layer of a lower refractive index dielectric immediately adjacent the front electrode 3. Thus, since the front electrode 3 is on the glass substrate 1, it will be appreciated that the word “on” as used herein covers both directly on and indirectly on with other layers therebetween.

Front glass substrate 1 and/or rear substrate 11 may be made of soda-lime-silica based glass in certain example embodiments of this invention. While substrates 1, 11 may be of glass in certain example embodiments of this invention, other materials such as quartz or the like may instead be used. Like electrode 3, substrate 1 may or may not be patterned in different example embodiments of this invention. Moreover, rear substrate or superstrate 11 is optional in certain instances. Glass 1 and/or 11 may or may not be thermally tempered in different embodiments of this invention.

The active semiconductor region or film 5 may include one or more layers, and may be of any suitable material. For example, the active semiconductor film 5 of one type of single junction amorphous silicon (a-Si) photovoltaic device includes three semiconductor layers, namely a p-layer, an n-layer and an i-layer. These amorphous silicon based layers of film 5 may be of hydrogenated amorphous silicon in certain instances, but may also be of or include hydrogenated amorphous silicon carbon or hydrogenated amorphous silicon germanium, or other suitable material(s) in certain example embodiments of this invention. It is possible for the active region 5 to be of a double-junction type in alternative embodiments of this invention.

Back contact, reflector and/or electrode 7 of the photovoltaic device may be of any suitable electrically conductive material. For example and without limitation, the optional back contact or electrode 7 may be of a TCO and/or a metal in certain instances. Example TCO materials for use as back contact or electrode 7 include indium zinc oxide, indium-tin-oxide (ITO), tin oxide, and/or zinc oxide which may be doped with aluminum (which may or may not be doped with silver). It is possible that the optional rear electrode 7 be sputter-deposited in the manner discussed above in connection with front electrode 3 in certain example instances. The TCO of the back electrode 7 may be of the single layer type or a multi-layer type in different instances. Moreover, the back electrode or contact 7 may include both a TCO portion and a metal portion in certain instances. For example, in an example multi-layer embodiment, the TCO portion of the back contact 7 may include a layer of a material such as indium zinc oxide (which may or may not be doped with silver, or the like), indium-tin-oxide (ITO), or the like closest to the active region 5, and another conductive and possibly reflective layer of a material such as silver, molybdenum, platinum, steel, iron, niobium, titanium, chromium, bismuth, antimony, or aluminum further from the active region 5 and closer to the substrate 11. The metal portion may be closer to substrate 11 compared to the TCO portion of the back contact/electrode 7.

The photovoltaic module may be encapsulated or partially covered with an encapsulating material such as encapsulant 9 in certain example embodiments. An example encapsulant or adhesive for layer 9 is EVA. However, other materials such as PVB, Tedlar type plastic, Nuvasil type plastic, Tefzel type plastic or the like may instead be used for layer 9 in different instances.

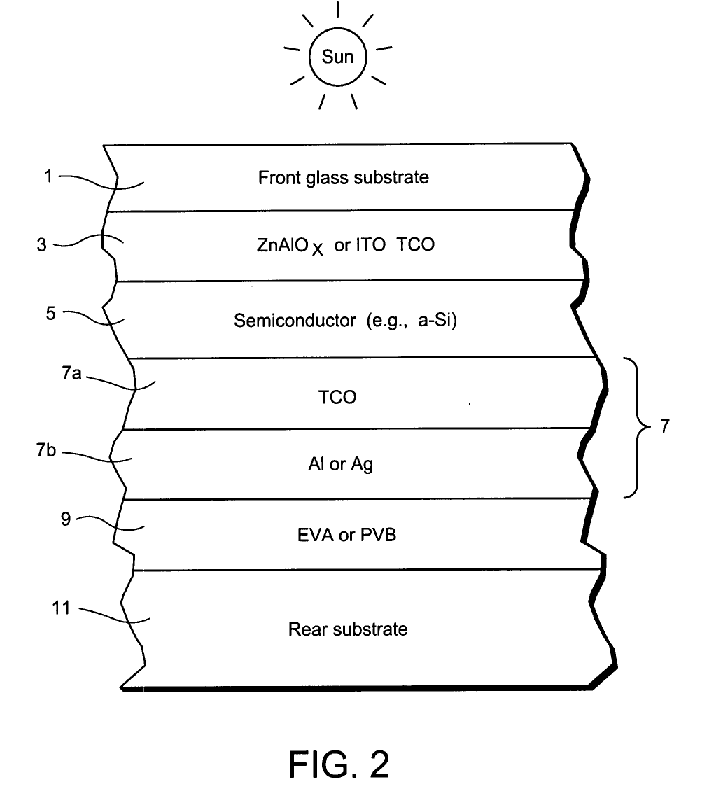

FIG. 2 is a cross sectional view of a photovoltaic device according to another example embodiment of this invention. The device of FIG. 2 is similar to that of FIG. 1, except that the rear electrode/reflector 7 is illustrated in FIG. 2 as including both a TCO portion 7a and a metal portion 7b. For example, in an example multi-layer embodiment, the TCO portion 7a of the back electrode 7 may include a layer 7a of a material such as indium zinc oxide (which may or may not be doped with silver, or the like), indium-tin-oxide (ITO), ZnOₓ, tin oxide, or the like closest to the active region 5, and another conductive and possibly reflective layer 7b of a material such as silver, molybdenum, platinum, steel, iron, niobium, titanium, chromium, bismuth, antimony, or aluminum further from the active region 5 and closer to the substrate 11. Front electrode 3 in the FIG. 2 embodiment may be made in the same manner and/or of the same material(s) discussed above in connection with the FIG. 1 embodiment.

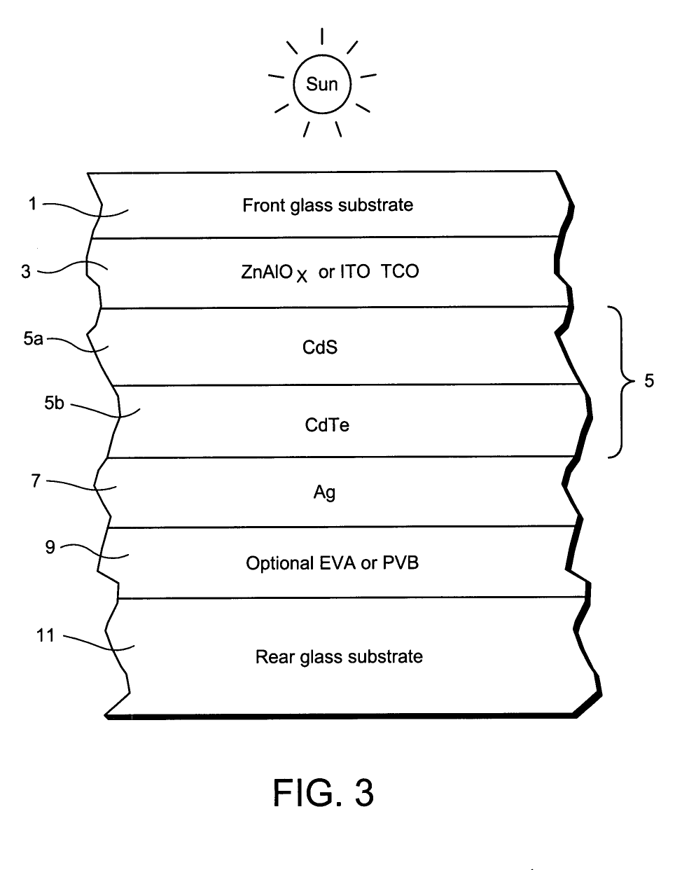

FIG. 3 is a cross sectional view of a CdTe type photovoltaic device according to another example embodiment of this invention. The device of FIG. 3, in this particular example, is similar to that of FIGS. 2-3 except that the semiconductor film 5 is shown as including both a CdS inclusive or based layer 5a and a CdTe inclusive or based layer 5b, and silver is used as an example material for the rear electrode or reflector 7 in this example. Front electrode 3 in the FIG. 3 embodiment may be made in the same manner and/or of the same material(s) discussed above in connection with the FIG. 1 embodiment.

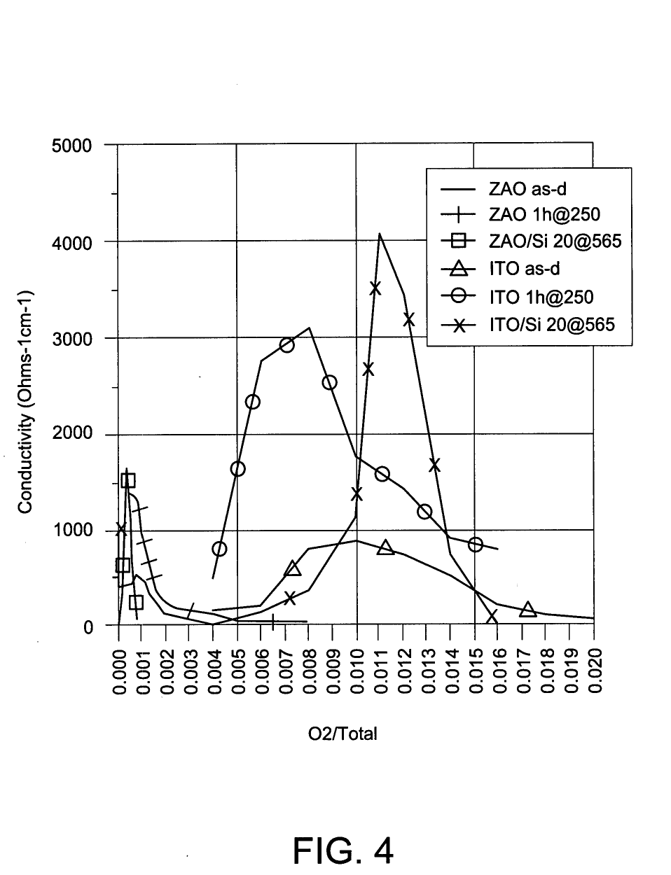

FIG. 4 is a conductivity versus gas ratio graph illustrating advantages of certain gas ratios used in sputter-depositing coating/electrode 3 according to certain example embodiments of this invention. For example, FIG. 4 illustrates that when sputter-depositing a zinc aluminum oxide (ZAO, in this case zinc aluminum oxide doped with 2% Al) coating/electrode 3 on a glass substrate 1 using a zinc aluminum oxide target in an atmosphere include argon and oxygen gases, the best (highest) electrical conductivity of the coating/electrode 3 was achieved, before and after heat treatment, when using an oxygen gas to total gas ratio (e.g., O₂/(Ar+O₂) ratio) of from 0 to 0.0025, more preferably from about 0.00001 to 0.0025, still more preferably from about 0.0001 to 0.002, even more preferably from about 0.0001 to 0.0015, and most preferably from about 0.0001 to 0.0010, with an example best ratio being about 0.0005 where the highest conductivity was achieved (see the spike at the left side of the graph).

FIG. 4 also illustrates that when sputter-depositing an ITO (indium-tin-oxide) TCO coating/electrode 3 on a glass substrate 1 using an ITO target in an atmosphere including argon and oxygen gases, the best (highest) electrical conductivity of the coating/electrode 3 was achieved, before and/or after heat treatment, when using an oxygen gas to total gas ratio (e.g., O₂/(Ar+O₂) ratio) of from 0.003 to 0.017, more preferably from about 0.004 to 0.016, still more preferably from about 0.005 to 0.015, even more preferably from about 0.008 to 0.014, with an example ratio being about 0.011. It can be seen in FIG. 4 that in an as-deposited (as-d) form (i.e., before any subsequent heat treatment), the highest conductivity for ITO coating/electrode 3 was achieved when the gas ratio was from about 0.007 to 0.016, more preferably from about 0.008 to 0.014. It can also be seen that after a one hour heat treatment at 250 degrees C. (1 h@250), the highest conductivity for ITO coating/electrode 3 was achieved when the gas ratio was from about 0.005 to 0.015, more preferably from about 0.006 to 0.009. It can also be seen in FIG. 4 that after heat treatment for twenty minutes at 565 degrees C. (20@565), the highest conductivity for ITO coating/electrode 3 was achieved when the gas ratio was from about 0.010 to 0.014, more preferably from about 0.011 to 0.013.

Moreover, it has also been found that the optional subsequent heat processing (e.g., at the high temperatures discussed herein) significantly improves the crystallinity of ITO and zinc oxide (optionally doped with Al) coatings/electrodes 3 thereby improve electro-optical properties thereof.

While oxygen is used in combination with argon (Ar) gas in certain example embodiments of this invention, this invention is not so limited. For example, other gas such as Kr or the like may be used to replace or supplement Ar gas in certain example embodiments of this invention.

While the invention has been described in connection with what is presently considered to be the most practical and preferred embodiment, it is to be understood that the invention is not to be limited to the disclosed embodiment, but on the contrary, is intended to cover various modifications and equivalent arrangements included within the spirit and scope of the appended claims.

1. A method of making a photovoltaic device, the method comprising:
providing a glass substrate;
sputtering at least one ceramic target in an atmosphere in order to deposit a substantially transparent conductive electrode comprising zinc oxide on the glass substrate;
wherein the ceramic target comprises zinc oxide;
wherein the atmosphere in which the target is sputtered includes both argon and oxygen gas and has an oxygen gas to total gas ratio of from 0.00001 to 0.0025; and
using the glass substrate with at least the electrode thereon in making a photovoltaic device which includes at least one semiconductor film.

2. The method of claim 1, wherein said using the glass substrate with at least the electrode thereon in making the photovoltaic device comprises coupling the glass substrate to another glass substrate with at least the electrode and the semiconductor film therebetween.

3. The method of claim 1, wherein the semiconductor film comprises amorphous silicon or CdTe.

4. The method of claim 1, wherein the photovoltaic device further comprises a back electrode and/or reflector located between at least another glass substrate and the semiconductor film.

5. The method of claim 1, wherein the electrode further comprises aluminum, and wherein the electrode contains more zinc than aluminum and has a sheet resistance (Rₛ) of less than about 50 ohms/square.

6. The method of claim 1, wherein the electrode has a sheet resistance (Rₛ) of no more than about 15 ohms/square.

7. The method of claim 1, wherein the electrode further comprises aluminum and the aluminum content of the electrode and/or target is from about 1-5%.

8. The method of claim 1, wherein the electrode directly contacts the glass substrate.

9. The method of claim 1, further comprising forming an antireflective coating on the glass substrate so that the antireflective coating is located between the glass substrate and the electrode.

10. The method of claim 1, wherein the atmosphere in which the target is sputtered has an oxygen gas to total gas ratio of from 0.0001 to 0.002.

11. The method of claim 1, wherein the atmosphere in which the target is sputtered has an oxygen gas to total gas ratio of from 0.0001 to 0.0015.

12. A method of making an electrode for use in an electronic device, the method comprising:
providing a glass substrate;
sputtering at least one ceramic target in an atmosphere in order to deposit a substantially transparent conductive electrode comprising zinc oxide on the glass substrate;
wherein the ceramic target comprises zinc oxide; and
wherein the atmosphere in which the target is sputtered includes both argon and oxygen gas and has an oxygen gas to total gas ratio of from 0.00001 to 0.0025.

13. The method of claim 12, further comprising providing a semiconductor film comprising amorphous silicon or CdTe adjacent the electrode.

14. The method of claim 12, wherein the electrode further comprises aluminum, and wherein the electrode contains more zinc than aluminum and has a sheet resistance (Rₛ) of less than about 50 ohms/square.

15. The method of claim 12, wherein the electrode further comprises aluminum and the aluminum content of the electrode and/or target is from about 1-5%.

16. The method of claim 12, wherein the atmosphere in which the target is sputtered has an oxygen gas to total gas ratio of from 0.0001 to 0.002.

17. The method of claim 12, wherein the atmosphere in which the target is sputtered has an oxygen gas to total gas ratio of from 0.0001 to 0.0015.

18. A method of making a photovoltaic device, the method comprising:
providing a glass substrate;
sputtering at least one ceramic target in an atmosphere in order to deposit a substantially transparent conductive electrode comprising indium tin oxide on the glass substrate;
wherein the ceramic target comprises indium tin oxide;
wherein the atmosphere in which the target is sputtered includes both argon and oxygen gas and has an oxygen gas to total gas ratio of from 0.003 to 0.017; and
using the glass substrate with at least the electrode thereon in making a photovoltaic device which includes at least one semiconductor film.

19. The method of claim 18, wherein said using the glass substrate with at least the electrode thereon in making the photovoltaic device comprises coupling the glass substrate to another glass substrate with at least the electrode and the semiconductor film therebetween.

20. The method of claim 18, wherein the semiconductor film comprises amorphous silicon or CdTe.

21. The method of claim 18, wherein the electrode has a sheet resistance (Rₛ) of less than about 50 ohms/square.

22. The method of claim 18, wherein the electrode directly contacts the glass substrate.

23. The method of claim 18, further comprising forming an antireflective coating on the glass substrate so that the antireflective coating is located between the glass substrate and the electrode.

24. The method of claim 18, wherein the atmosphere in which the target is sputtered has an oxygen gas to total gas ratio of from 0.004 to 0.016.

25. The method of claim 18, wherein the atmosphere in which the target is sputtered has an oxygen gas to total gas ratio of from 0.005 to 0.015.

26. A method of making an electrode for use in an electronic device, the method comprising:
providing a glass substrate;
sputtering at least one ceramic target in an atmosphere in order to deposit a substantially transparent conductive electrode comprising indium tin oxide on the glass substrate;
wherein the ceramic target comprises indium tin oxide; and
wherein the atmosphere in which the target is sputtered includes both argon and oxygen gas and has an oxygen gas to total gas ratio of from 0.003 to 0.017.

27. The method of claim 26, further comprising providing a semiconductor film comprising silicon or CdTe adjacent the electrode.

28. The method of claim 26, wherein the atmosphere in which the target is sputtered has an oxygen gas to total gas ratio of from 0.004 to 0.016.

29. The method of claim 26, wherein the atmosphere in which the target is sputtered has an oxygen gas to total gas ratio of from 0.008 to 0.014.

30. The method of claim 26, wherein the target comprises more indium than tin.
